(19) United States
(12) Patent Application Publication
(10) Pub. No.: US 2026/0312695 A1
(43) Pub. Date: Oct. 8, 2026

(54) OPTICAL RECEIVER

(71) Applicant: Nippon Telegraph and Telephone Corporation, Tokyo (JP)

(72) Inventors: Shohei Kosuga, Musashino-shi, Tokyo (JP); Shigeru Kanazawa, Musashino-shi, Tokyo (JP)

(21) Appl. No.: 18/880,692

(22) PCT Filed: Jul. 5, 2022
(86) PCT No.: PCT/JP2022/026702

§ 371 Date: Jan. 2, 2025

(51) Int. Cl. H04B 10/69; H05K 1/02; H05K 1/181

(52) U.S. Cl. CPC H04B 10/6911; H04B 10/693; H05K 1/0243; H05K 1/181; H05K 2201/10015; H05K 2201/10174; H05K 2201/10287; H05K 2201/10522; H05K 2201/1053

(57) ABSTRACT

An optical receiver in which an operating band is less likely to deteriorate even in a case where a distance between elements constituting the optical receiver changes is provided. An optical receiver of an embodiment includes: a light receiving element (PD); a bias circuit that applies a bias voltage; a transimpedance amplifier (TIA); at least one subcarrier on which the PD, the bias circuit, and the TIA are mounted; and at least one high frequency wiring board that creates at least one of connection between an upper surface of the PD and an upper surface of the bias circuit and connection between the upper surface of the PD and an upper surface of the TIA.

### TECHNICAL FIELD

The present disclosure relates to an optical receiver, and more specifically, to an optical semiconductor module mounting technique for the optical receiver.

### BACKGROUND ART

In the past, an optical receiver including a photodiode (PD) that is a light receiving element, a bias circuit for driving the PD, and a transimpedance amplifier (TIA) has been known (for example, see Non Patent Literature 1). In particular, in a case where the light receiving element is an avalanche photodiode (APD), it is difficult to drive the light receiving element with a supply voltage from the TIA, and thus a bias circuit is separately required.

FIG. 1 shows views showing a schematic configuration of a conventional optical receiver. FIG. 1(a) is a top view, and FIG. 1(b) is a cross-sectional view. An optical receiver 100 shown in FIG. 1 includes a PD 101, a bias circuit 102 for driving the PD 101, and a TIA 104 that is an electric amplifier.

The PD 101 and the bias circuit 102 are disposed on a PD subcarrier 103, and the TIA 104 is disposed on a TIA subcarrier 105 different from the PD subcarrier 103. The PD subcarrier 103 and the TIA subcarrier 105 are dielectric carriers.

The bias circuit 102 is a capacitor constituting a bias circuit, and applies a reverse bias to the PD 101 connected thereto. The TIA 104 converts a current from the connected PD 101 connected thereto into a voltage. The bias circuit (capacitor) 102 positioned closest to the PD 101 affects high frequency characteristics of the optical receiver 100.

A certain distance is provided between the bias circuit 102 and the PD 101 and between the PD 101 and the TIA 104. The PD 101 and the bias circuit 102 are electrically connected by a metal wire 106a. Similarly, the PD 101 and the TIA 104 are electrically connected by a metal wire 106b.

The PD subcarrier 103 has a through hole, and an opening portion 103a is formed of the through hole. The PD 101 is disposed on the PD subcarrier 103 so that signal light enters a light receiving surface on the back side of the PD 101 through the opening portion 103a.

### CITATION LIST

### Non Patent Literature

Non Patent Literature 1: H. T. Chen et. al., “Low-voltage waveguide Ge APD based high sensitivity 10 Gb/s Si photonic receiver”, 2015 European Conference on Optical Communication, Tu1.3.4.

### SUMMARY OF INVENTION

### Technical Problem

In order to transmit a signal photoelectrically converted in the optical receiver as described above, the elements constituting the optical receiver are required to be electrically connected to each other. A metal wire is generally used for electrical connection between the elements. The metal wire affects frequency response characteristics of the optical receiver. Accordingly, in order to operate the optical receiver in a wide band, it is required to mount a wire having an appropriate length in consideration of the frequency characteristics of each element. For example, a wire of about 100 um is mounted in an optical receiver in a class of >100 Gbaud to apply a slight peaking to the frequency characteristics, whereby a wide band is achieved. In order to mount a wire having an optimum length, it is necessary to provide a corresponding distance between the elements. In addition, the band may change owing to variations of the wire length due to the tolerance in mounting. Therefore, in the wire mounting, a problem occurs in that the degree of freedom in the structural design of the optical receiver is limited.

### Solution to Problem

The present disclosure is contrived in view of these problems, and an object thereof is to provide an optical receiver in which an operating band is less likely to deteriorate even in a case where a distance between elements constituting the optical receiver changes.

In order to achieve the object, an optical receiver of an embodiment of the present invention includes: a light receiving element (PD) ; a bias circuit that applies a bias voltage; transimpedance amplifier (TIA); at least one subcarrier on which the PD, the bias circuit, and the TIA are mounted; and at least one high frequency wiring board that creates at least one of connection between an upper surface of the PD and an upper surface of the bias circuit and connection between the upper surface of the PD and an upper surface of the TIA.

### Advantageous Effects of Invention

According to this configuration, it is possible to provide an optical receiver in which an operating band is less likely to deteriorate even in a case where a distance between elements constituting the optical receiver changes.

### BRIEF DESCRIPTION OF DRAWINGS

FIG. 1 shows views showing a schematic configuration of a conventional optical receiver. FIG. 1(a) is a top view, and FIG. 1(b) is a cross-sectional view.

FIG. 2 shows views showing a schematic configuration of an optical receiver according to an embodiment of the present disclosure. FIG. 2(a) is a top view, FIG. 2(b) is a cross-sectional view, FIG. 2(c) is a top view of a high frequency waveguide substrate, and FIG. 2(d) is a cross-sectional view of the high frequency waveguide substrate.

FIG. 3 shows views showing a schematic configuration of an optical receiver according to an embodiment of the present disclosure. FIG. 3(a) is a top view, FIG. 3(b) is a cross-sectional view, FIG. 3(c) is a top view of a high frequency waveguide substrate, and FIG. 3(d) is a cross-sectional view of the high frequency waveguide substrate.

FIG. 4 shows views showing a schematic configuration of an optical receiver according to an embodiment of the present disclosure. FIG. 4(a) is a top view, FIG. 4(b) is a cross-sectional view, FIG. 4(c) is a top view of a high frequency waveguide substrate, and FIG. 4(d) is a cross-sectional view of the high frequency waveguide substrate.

FIG. 5 shows views showing a schematic configuration of an optical receiver according to an embodiment of the present disclosure. FIG. 5(a) is a top view, FIG. 5(b) is a cross-sectional view, FIG. 5(c) is a top view of a high frequency waveguide substrate, and FIG. 5(d) is a cross-sectional view of the high frequency waveguide substrate.

FIG. 6 shows views showing a schematic configuration of an optical receiver according to an embodiment of the present disclosure. FIG. 6(a) is a top view, FIG. 6(b) is a cross-sectional view, FIG. 6(c) is a top view of a high frequency waveguide substrate, and FIG. 6(d) is a cross-sectional view of the high frequency waveguide substrate.

FIG. 7 shows views showing a schematic configuration of an optical receiver according to an embodiment of the present disclosure. FIG. 7(a) is a top view, FIG. 7(b) is a cross-sectional view, FIG. 7(c) is a top view of a high frequency waveguide substrate, and FIG. 7(d) is a cross-sectional view of the high frequency waveguide substrate.

FIG. 8 shows views showing a schematic configuration of an optical receiver according to an embodiment of the present disclosure. FIG. 8(a) is a top view, FIG. 8(b) is a cross-sectional view, FIG. 8(c) is a top view of a high frequency waveguide substrate, and FIG. 8(d) is a cross-sectional view of the high frequency waveguide substrate.

FIG. 9 is a view showing frequency response characteristics of an output unit of a TIA of the optical receiver when 50-Gbaud signal light is received.

FIG. 10 is a view showing frequency response characteristics of an output unit of a TIA of the optical receiver when 100-Gbaud signal light is received.

### DESCRIPTION OF EMBODIMENTS

Hereinafter, embodiments of the present disclosure will be described in detail with reference to the drawings. The same or similar reference numerals denote the same or similar components, and repetitive description thereof will be omitted. The numerical values exemplified in the following description are not limited, and other numerical values can be used without departing from the gist of the present disclosure. In the present specification, the Z direction in the XY plane is referred to as the vertical direction.

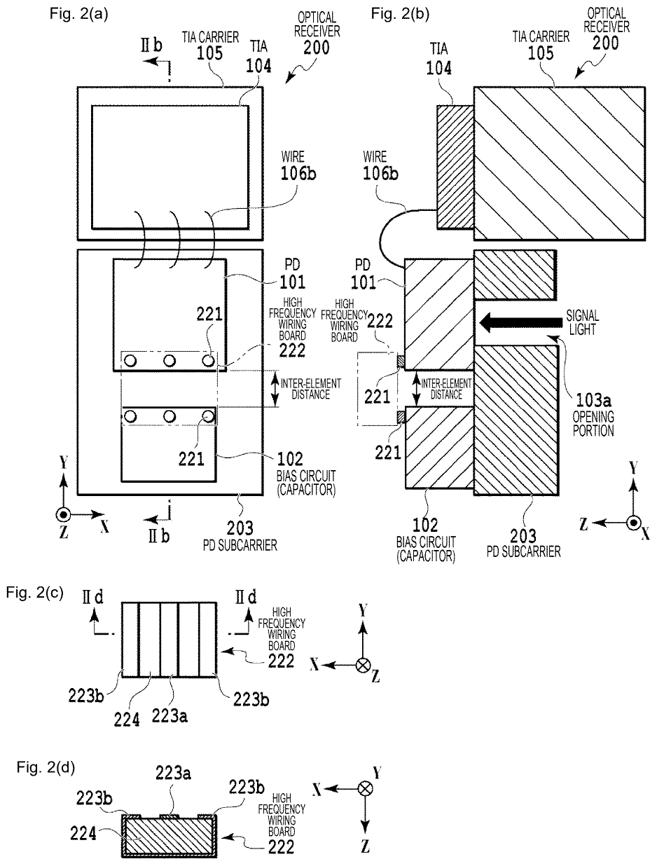

In an optical receiver according to an embodiment of the present disclosure, as shown in FIGS. 2 to 8, a high frequency wiring board is used instead of a metal wire for all or any number of connections between elements constituting the optical receiver. The above-described conventional optical receiver has a problem in that, in a case where a distance between the elements constituting the optical receiver is away from an optimum value, the length of the metal wire changes and the band of the optical receiver deteriorates. In contrast, in the configuration of the optical receiver according to the embodiment of the present disclosure, the deterioration of the band of the optical receiver can be reduced by using the high frequency wiring board, that is a line in which an impedance line and a high impedance line are combined, for electrical connection between the elements.

### Embodiment 1

An optical receiver according to Embodiment 1 of the present disclosure will be described with reference to FIG. 2. FIG. 2(a) is a top view of an optical receiver 200 of the present embodiment, and FIG. 2(b) is a cross-sectional view of the optical receiver 200 of the present embodiment. The optical receiver 200 shown in FIG. 2 includes a PD 101, a bias circuit 102, a TIA 104, a PD subcarrier 203, and a TIA subcarrier 105.

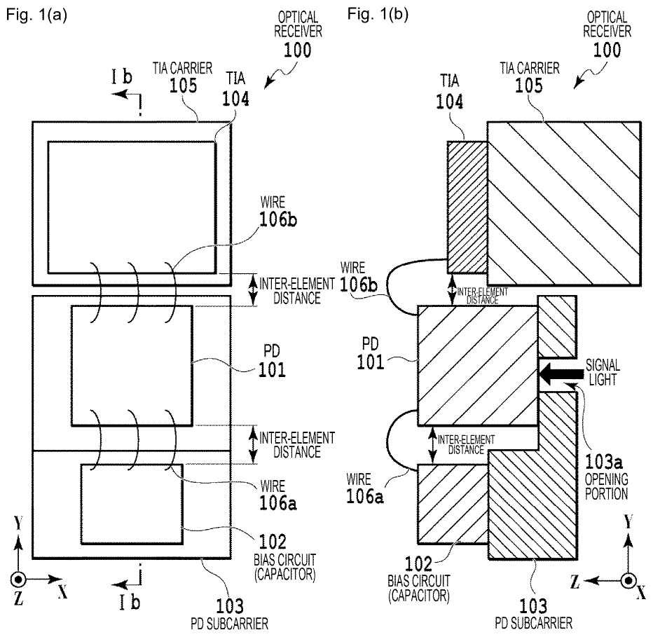

The PD 101 and the bias circuit 102 are disposed on upper surfaces of two facing main surfaces (XY plane) of the PD subcarrier 203 that is a dielectric carrier. The PD subcarrier 203 is different from the PD subcarrier 103 having a step on an upper surface shown in FIG. 1 in that the two facing main surfaces of the PD subcarrier 203 are substantially parallel to each other.

The TIA 104 is disposed on upper surfaces of two facing main surfaces (XY plane) of the TIA subcarrier 105 that is a dielectric carrier.

Similarly to the optical receiver 100 described with reference to FIG. 1, the optical receiver 100 is provided with a certain distance between the bias circuit 102 and the PD 101 and between the PD 101 and the TIA 104. The PD 101 and the TIA 104 are electrically connected by a metal wire 106b.

The optical receiver 200 shown in FIG. 2 is different from the optical receiver 100 in FIG. 1 in that a high frequency wiring board 222 is used instead of the metal wire 106a for electrical connection between the PD 101 and the bias circuit (capacitor) 102. The high frequency wiring board 222 is formed of a line in which an impedance line and a high impedance line are combined by appropriately designing a structure and a dielectric material. In addition, the optical receiver 200 is configured so that the heights of a connection surface that is the upper surface of the PD 101 and a connection surface that is the upper surface of the bias circuit 102, bridged by the high frequency wiring board 222, coincide with each other. By polishing the PD 101, the connection surface of the PD 101 and the connection surface of the bias circuit 102 can be aligned in height.

The line impedance in the high frequency wiring board 222 can be adjusted by changing the width (in the X-axis direction) of a line 223a in the high frequency wiring board 222. Specifically, in a case where the line 223a has a part whose width is small, the impedance of the part increases. By reducing the width of a part of the line 223a designed to have a width corresponding to a specific impedance (for example, 50 Q), a part of the line 223a becomes a line having a large impedance, that is, a high impedance line. In the present disclosure, a part of the line 223a having a width corresponding to a specific impedance is expressed as an impedance line. The high frequency wiring board 222 in which the impedance line and the high impedance line are combined as described above can be realized by reducing the width of a part of the line 223a as above. The high frequency wiring board 222 in which the impedance line and the high impedance line are combined may be realized by partially changing the dielectric material constituting the high frequency wiring board 222, or by designing the structure of the high frequency wiring board 222 and the combination of the dielectric material.

FIG. 2 (c) is a bottom view of the high frequency wiring board 222, and FIG. 2(d) is a cross-sectional view of the high frequency wiring board 222. As shown in FIG. 2, the high frequency wiring board 222 has metal thin films formed on four surfaces of a dielectric 224 except for two The metal thin films formed on a lower surface of the dielectric 224, that is, on a surface facing the upper surfaces of the PD 101 and the bias circuit 102 are separated by slits. The thin film positioned at a center of the lower surface of the dielectric 224 constitutes the line 223a. The thin film positioned on the side of the lower surface of the dielectric 224 and separated from the line 223a by the slit is continuous with the thin films formed on the side surface (YZ surface) and the upper surface of the dielectric 224, and constitutes a line 223b. The line 223a is at a given bias potential shared by the bias circuit 102, and the line 223b is at a reference potential such as ground. The line 223a and the line 223b of the high frequency wiring board 222 are disposed in contact with bumps 221 formed on the upper surfaces of the PD 101 and the bias circuit 102.

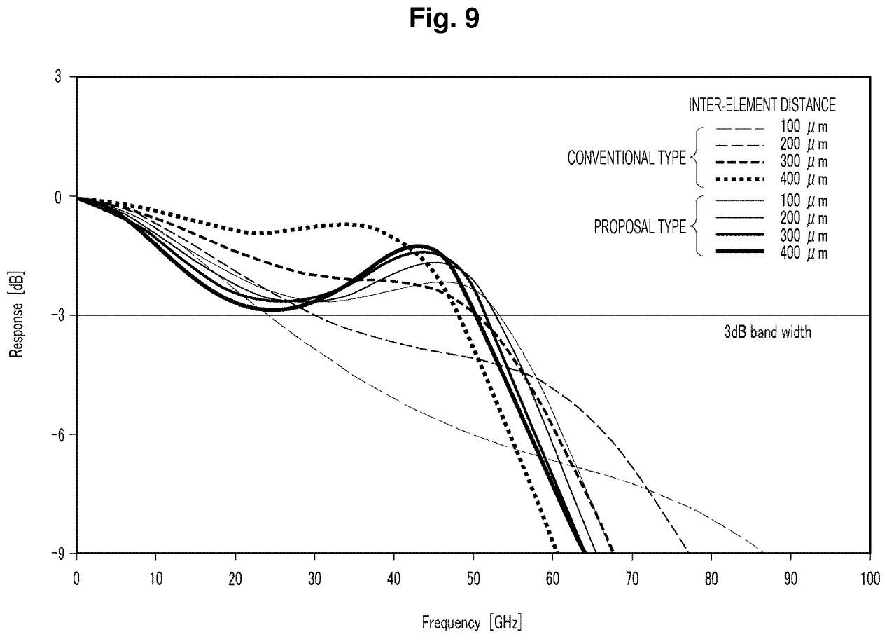

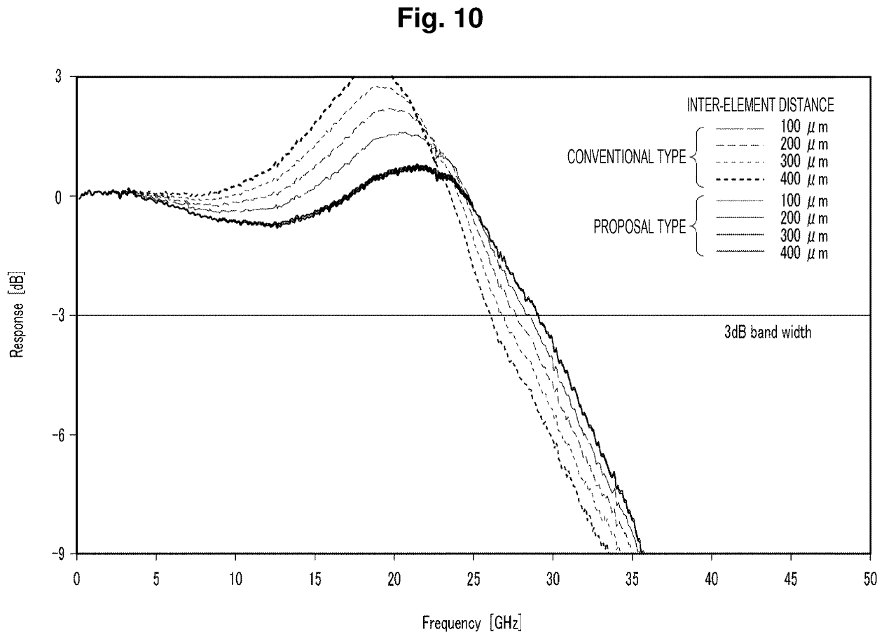

FIG. 9 is a view showing frequency response characteristics of an output unit of the TIA 104 at 50 Gbaud. FIG. 10 is a view showing frequency response characteristics of the output unit of the TIA 104 at 100 Gbaud. In FIGS. 9 and 10, the characteristics in the conventional optical receiver as shown in FIG. 1 are indicated by broken lines, and the characteristics in the optical receiver according to the embodiment of the present disclosure are indicated by solid lines. The characteristics shown in FIGS. 9 and 10 indicate frequency characteristics calculated while changing the distance (inter-element distance) between the PD and the bias circuit and between the PD and the TIA in the optical receiver.

First, referring to the frequency response characteristics of the conventional optical receiver in FIG. 9, the frequency is 51.0 GHZ in the 3-dB band when the inter-element distance is 300 μm, and a band of 50 GHz or more, that is the Nyquist frequency associated with a 100-Gbaud signal, can be ensured. However, it can be confirmed that the frequency in the 3-dB band decreases and falls below 50 GHZ as the inter-element distance changes. On the other hand, in the proposal type optical receiver of the present disclosure, that is, in the optical receiver using the high frequency wiring board in which the impedance components of the line 223a and the line 223b are changed according to the inter-element distance, the drop of the frequency in the 3-dB band due to the change in the inter-element distance is smaller than in the case of wire mounting, and the frequency in the 3-dB band is 50 GHZ or more at any inter-element distance. As described above, it is found that in the proposal type optical receiver of the present disclosure, it is possible to achieve a band of 50 GHZ or more, that is the Nyquist frequency associated with the 100-Gbaud signal.

Next, referring to the frequency characteristics at 100 Gbaud in FIG. 10, in the conventional optical receiver, the frequency for securing a given response such as the 3-dB band decreases according to the change in the inter-element distance, but such a drop of the frequency is not observed in the proposal type optical receiver of the present disclosure.

From the above description, it has been shown that in the proposal type optical receiver of the present disclosure, it is possible to further suppress a drop of the frequency for ensuring a given frequency response due to an increase of the inter-element distance and variations of the inter-element distance that may occur during mounting than in the conventional optical receiver. In the present embodiment, the verification is performed with the baud rates of 100 Gbaud and 50 Gbaud, but the same effects can be obtained by redesigning the high frequency wiring board according to the baud rate to be applied.

### Embodiment 2

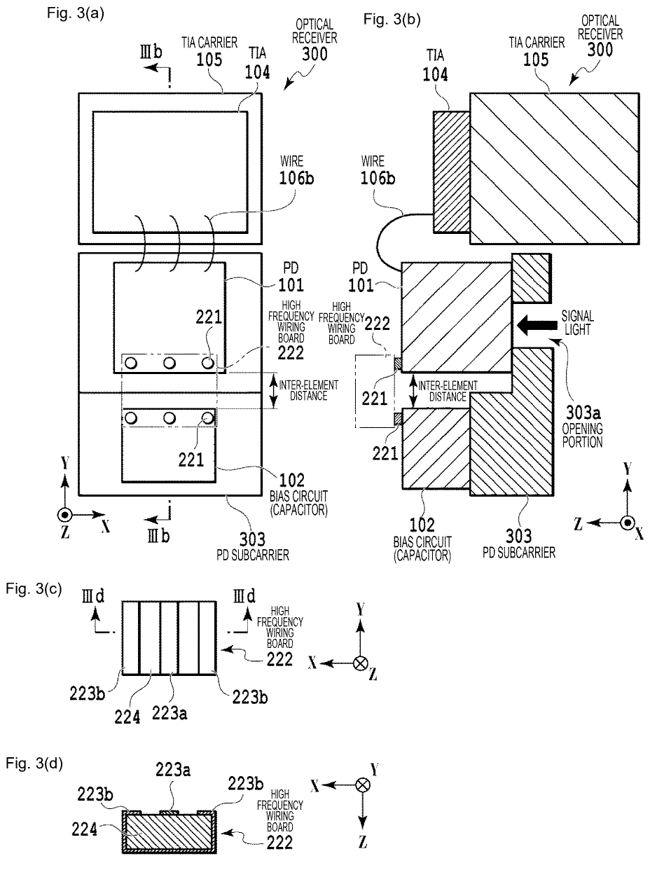

An optical receiver according to Embodiment 2 of the present disclosure will be described with reference to FIG. 3. FIG. 3(a) is a top view of an optical receiver 300 of the present embodiment, and FIG. 3(b) is a cross-sectional view of the optical receiver 300 of the present embodiment. FIG. 3(c) is a bottom view of a high frequency wiring board 222, and FIG. 3(d) is a cross-sectional view of the high frequency wiring board 222.

The optical receiver 300 shown in FIG. 3 is different from the optical receiver 200 described with reference to FIG. 2, that is, the optical receiver 200 having a configuration in which the height is aligned by polishing the PD 101 disposed on the upper surface of the PD subcarrier 203 with no step, in that the upper surface of the PD 101 and the upper surface of the bias circuit 102 bridged by the high frequency wiring board are aligned in height by a step provided on an upper surface of a PD subcarrier 303. In the configuration of the present embodiment, since it is not necessary to polish the PD, the operation reliability of the PD is not impaired. The PD subcarrier 303 on which the back-side incident type PD 101 is mounted includes an opening portion 303a formed of a through hole.

Other configurations of the optical receiver 300 are similar to those of the optical receiver 200. The optical receiver 300 of the present embodiment also has effects similar to those of the optical receiver 200 of Embodiment 1.

### Embodiment 3

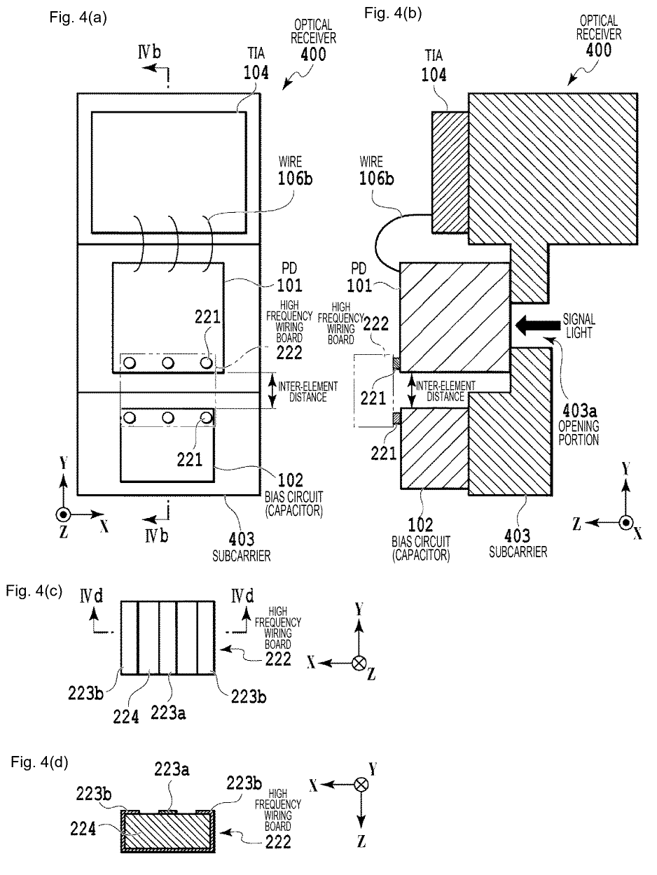

An optical receiver according to Embodiment 3 of the present disclosure will be described with reference to FIG. 4. FIG. 4(a) is a top view of an optical receiver 400 of the present embodiment, and FIG. 4(b) is a cross-sectional view of the optical receiver 400 of the present embodiment. FIG. 4(c) is a bottom view of a high frequency wiring board 222, and FIG. 4(d) is a cross-sectional view of the high frequency wiring board 222.

The optical receiver 400 shown in FIG. 4 is different from the optical receiver 300 described with reference to FIG. 3 in that the bias circuit (capacitor) 102, the PD 101, and the TIA 104 are installed on a single subcarrier 403. With the configuration of the present embodiment, the number of members to be used can be reduced as compared with the configurations of Embodiments 1 and 2. The subcarrier 403 is a dielectric carrier. A configuration is provided in which the upper surface of the PD 101 and the upper surface of the bias circuit 102 bridged by the high frequency wiring board are aligned in height by a step provided on an upper surface of the subcarrier 403. The PD subcarrier 403 on which the back-side incident type PD 101 is mounted includes an opening portion 403a formed of a through hole.

Other configurations of the optical receiver 400 are similar to those of the optical receiver 200. The optical receiver 400 of the present embodiment also has effects similar to those of the optical receiver 200 of Embodiment 1.

### Embodiment 4

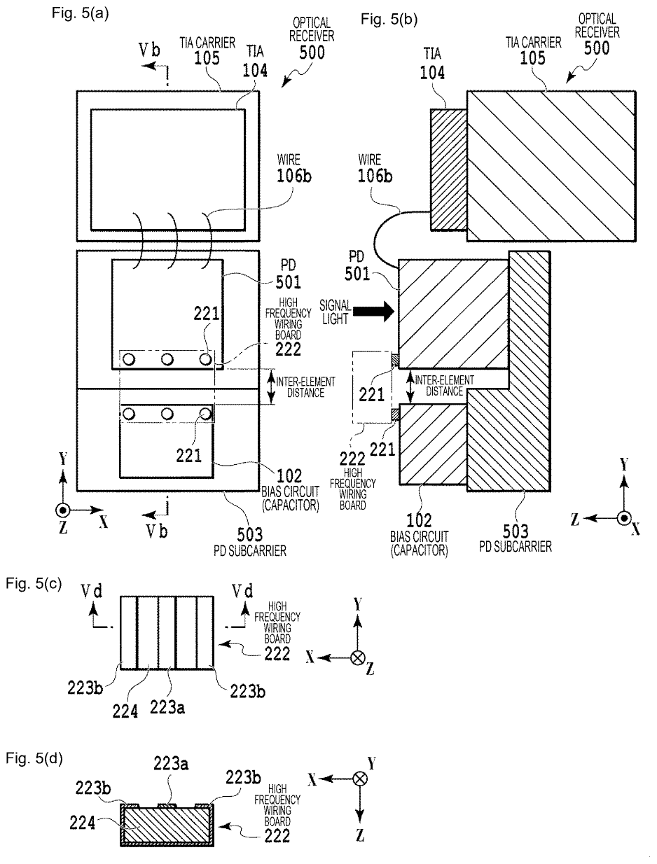

An optical receiver according to Embodiment 4 of the present disclosure will be described with reference to FIG. 5. FIG. 5(a) is a top view of an optical receiver 500 of the present embodiment, and FIG. 5(b) is a cross-sectional view of the optical receiver 500. FIG. 5(c) is a bottom view of a high frequency wiring board 222, and FIG. 5(d) is a cross-sectional view of the high frequency wiring board 222.

The optical receiver 500 shown in FIG. 5 has a configuration in which a front-side incident type PD 501 is adopted instead of the back-side incident type PD 201 in the optical receiver 300 described with reference to FIG. 3. As shown in FIG. 5, in a PD subcarrier 503 of the optical receiver 500, it is not necessary to provide an opening portion formed of a through hole through which signal light passes, and the mounting process can be reduced. The subcarrier 503 is a dielectric carrier. A configuration is provided in which an upper surface of the PD 501 and an upper surface of the bias circuit 102 bridged by the high frequency wiring board are aligned in height by a step provided on an upper surface of the subcarrier 503.

Other configurations of the optical receiver 500 are similar to those of the optical receiver 300. The optical receiver 500 of the present embodiment also has effects similar to those of the optical receiver 300 of Embodiment 2, that is, those of the optical receiver 200 of Embodiment 1.

### Embodiment 5

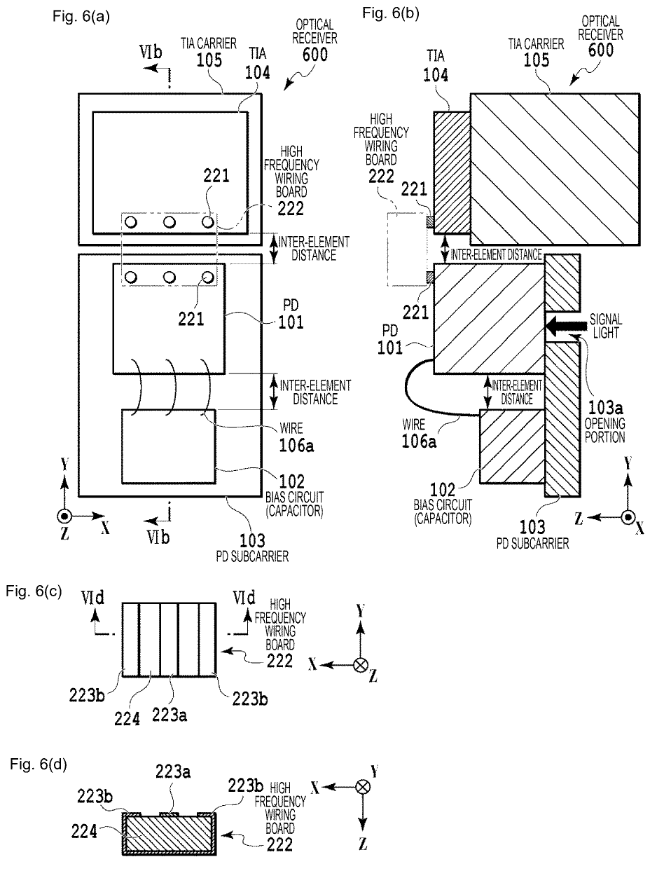

An optical receiver according to Embodiment 5 of the present disclosure will be described with reference to FIG. 6. FIG. 6(a) is a top view of an optical receiver 600 of the present embodiment, and FIG. 6(b) is a cross-sectional view of the optical receiver 600. FIG. 6(c) is a bottom view of a high frequency wiring board 222, and FIG. 6(d) is a cross-sectional view of the high frequency wiring board 222.

The optical receiver 600 shown in FIG. 6 has a configuration in which the metal wire 106a is used for connection between the bias circuit (capacitor) 102 and the PD 101 and the high frequency wiring board 222 is used for connection between the PD 101 and the TIA 104 in the optical receiver 300 described with reference to FIG. 3. The height of the TIA subcarrier 105 is adjusted to align the upper surface of the PD 101 with the upper surface of the TIA 104.

In the configuration of the optical receiver 600, the connection is easily made even in a case where the interval between the bumps 221 on the upper surface of the PD 101 is different from the interval between the bumps 221 on the upper surface of the TIA 104. For example, the PD 101 and the TIA 104 can be easily connected to each other by tapering the pattern of the line 223a and the line 223b formed on the back surface of the high frequency wiring board 222 according to the interval of the bumps 221.

Other configurations of the optical receiver 600 are similar to those of the optical receiver 300. The optical receiver 600 of the present embodiment also has effects similar to those of the optical receiver 300 of Embodiment 2, that is, those of the optical receiver 200 of Embodiment 1.

### Embodiment 6

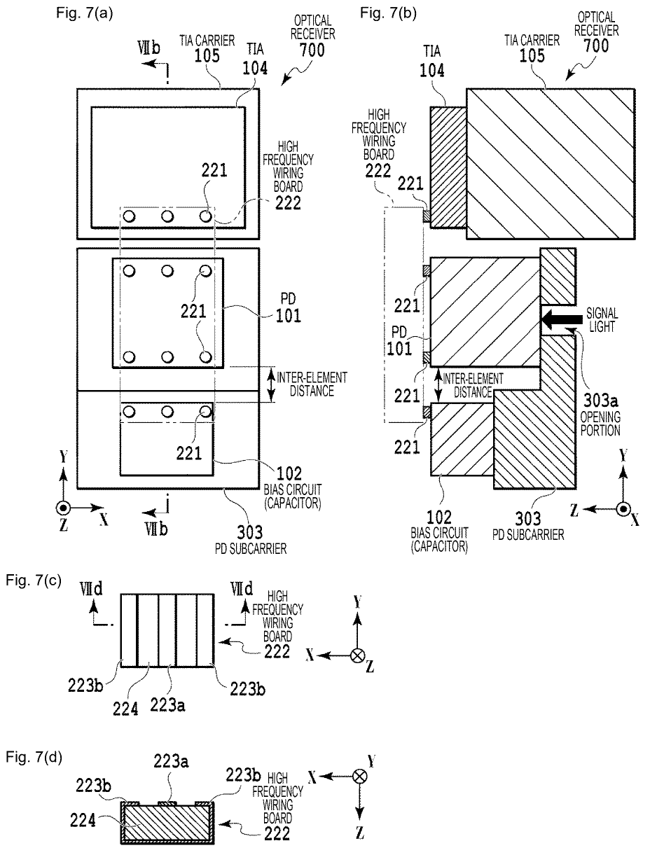

An optical receiver according to Embodiment 6 of the present disclosure will be described with reference to FIG. 7. FIG. 7(a) is a top view of an optical receiver 700 of the present embodiment, and FIG. 7(b) is a cross-sectional view of the optical receiver 700. FIG. 7(c) is a bottom view of a part of a high frequency wiring board 222, and FIG. 7(d) is a cross-sectional view of the high frequency wiring board 222.

The optical receiver 700 shown in FIG. 7 has a configuration in which instead of the metal wire 106b, the high frequency wiring board 222 is used for connection between the PD 101 and the TIA 104 in the optical receiver 300 described with reference to FIG. 3. The height of the TIA subcarrier 105 is adjusted to align the upper surface of the PD 101 with the upper surface of the TIA 104. A configuration is provided in which the length in the Y direction of the high frequency wiring board 222 used for connection between the PD 101 and the bias circuit (capacitor) 102 is increased in the optical receiver 300. The single high frequency wiring board 222 is disposed on the upper surfaces of the bias circuit 102, the PD 101, and the TIA 104, the bumps 221 provided on the upper surface of the bias circuit 102 and the bumps 221 provided on the upper surface of the PD 101 are connected by the lines 223a and 223b, and the bumps 221 provided on the upper surface of the PD 101 and the bumps 221 provided on the upper surface of the TIA 104 are connected by the lines 223a and 223b. The back surface of the single high frequency wiring board 222 is not provided with the lines 223a and 223b connecting the bumps 221 on the bias circuit 102 side and the bumps 221 on the TIA 104 side provided on the upper surface of the PD 101.

The optical receiver 700 shown in FIG. 7 can reduce the number of members for electrical connection between the elements and the number of steps for mounting. In addition, in the present embodiment, in a case where the front-side incident type PD 501 (FIG. 5) is used instead of the back-side incident type PD 201, signal light may be incident on the light receiving surface of the PD 501 by providing an opening portion formed of a through hole penetrating the upper surface and the lower surface in the central portion of the high frequency wiring board 222. Since the current distribution in the lines 223a and 223b of the high frequency wiring board 222 is concentrated at the electrode edge (around the bump 221), the deterioration of the high frequency electric signal due to the formation of the through hole in the central portion of the high frequency wiring board 222 hardly occurs.

Other configurations of the optical receiver 700 are similar to those of the optical receiver 300. The optical receiver 700 of the present embodiment also has effects similar to those of the optical receiver 300 of Embodiment 2, that is, those of the optical receiver 200 of Embodiment 1.

### Embodiment 7

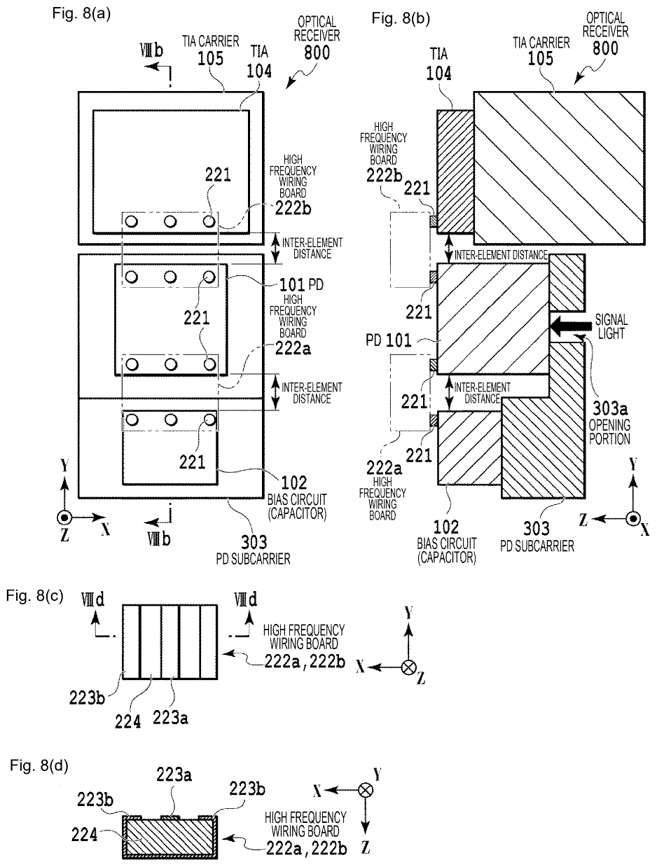

An optical receiver according to Embodiment 7 of the present disclosure will be described with reference to FIG. 8. FIG. 8(a) is a top view of an optical receiver 800 of the present embodiment, and FIG. 8(b) is a cross-sectional view of the optical receiver 800. FIG. 8(c) is a bottom view of high frequency wiring boards 222a and 222b, and FIG. 8(d) is a cross-sectional view of the high frequency wiring boards 222a and 222b.

The optical receiver 800 shown in FIG. 8 has a configuration in which instead of the metal wire 106b, the high frequency wiring board 222b is used for connection between the PD 101 and the TIA 104 in the optical receiver 300 described with reference to FIG. 3. The high frequency wiring board 222a corresponds to the high frequency wiring board 222 in the optical receiver 300 described with reference to FIG. 3. In the optical receiver 800, the height of the TIA subcarrier 105 is adjusted to align the upper surface of the PD 101 of the optical receiver 300 with the upper surface of the TIA 104.

In the optical receiver 800, the high frequency wiring board 222b connecting the PD 101 and the TIA 104 can be constituted by using a material different from the material constituting the high frequency wiring board 222 connecting the bias circuit 102 and the PD 101. In addition, in a case where the front-side incident type PD 501 is used instead of the back-side incident type PD 101, it is not necessary to form a through hole in the PD subcarrier 303, and thus the number of steps for mounting can be reduced.

Other configurations of the optical receiver 800 are similar to those of the optical receiver 300. The optical receiver 800 of the present embodiment also has effects similar to those of the optical receiver 300 of Embodiment 2, that is, those of the optical receiver 200 of Embodiment 1.

### INDUSTRIAL APPLICABILITY

An optical receiver in which an operating band is less likely to deteriorate even in a case where a distance between elements constituting the optical receiver changes is provided.

### REFERENCE SIGNS LIST

100, 200, 300, 400, 500, 600, 700, 800 OPTICAL RECEIVER

101, 501 Photodiode (PD)

102 Bias circuit (capacitor)

103, 203, 303 PD subcarrier

103a, 303a, 403a Opening portion (through hole)

104 Transimpedance amplifier (TIA)

105 TIA subcarrier

106a, 106b Wire

221 Bump

222, 222a, 222b High frequency wiring board

223a, 223b Line

224 Dielectric

403 Subcarrier

503 PD subcarrier

1. An optical receiver comprising:
a light receiving element (PD);
a bias circuit that applies a bias voltage;
a transimpedance amplifier (TIA);
at least one subcarrier on which the PD, the bias circuit, and the TIA are mounted; and
at least one high frequency wiring board that creates at least one of connection between an upper surface of the PD and an upper surface of the bias circuit and connection between the upper surface of the PD and an upper surface of the TIA.

2. The optical receiver according to claim 1,
wherein lower surfaces of the bias circuit, the PD, and the TIA face an upper surface of the at least one subcarrier, and
the upper surface of the bias circuit, the upper surface of the PD, and the upper surface of the TIA are connected by a single high frequency wiring board.

3. The optical receiver according to claim 1,
wherein lower surfaces of the bias circuit, the PD, and the TIA face an upper surface of the at least one subcarrier,
the upper surface of the bias circuit and the upper surface of the PD are connected by a first high frequency wiring board, and
the upper surface of the PD and the upper surface of the TIA are connected by a second high frequency wiring board separate from the first high frequency wiring board.

4. The optical receiver according to claim 1, wherein the PD is a back-side incident type PD.

5. The optical receiver according to claim 1, wherein the PD is a front-side incident type PD.

6. The optical receiver according to claim 1,
wherein the bias circuit and the PD are installed on an upper surface of a first subcarrier,
the TIA is installed on an upper surface of a second subcarrier, and
the first subcarrier and the second subcarrier are separated.

7. The optical receiver according to claim 1, wherein the bias circuit, the PD, and the TIA are installed on a single subcarrier.

8. The optical receiver according to claim 1, wherein at least one of height of the upper surface of the PD and height of the upper surface of the bias circuit connected by the high frequency wiring board, and height of the upper surface of the PD and height of the upper surface of the TIA connected by the high frequency wiring board is adjusted by at least one of a step provided on the upper surface of the subcarrier and polishing of the PD.

9. The optical receiver according to claim 2, wherein the PD is a back-side incident type PD.

10. The optical receiver according to claim 3, wherein the PD is a back-side incident type PD.

11. The optical receiver according to claim 2, wherein the PD is a front-side incident type PD.

12. The optical receiver according to claim 3, wherein the PD is a front-side incident type PD.

13. The optical receiver according to claim 2,
wherein the bias circuit and the PD are installed on an upper surface of a first subcarrier,
the TIA is installed on an upper surface of a second subcarrier, and
the first subcarrier and the second subcarrier are separated.

14. The optical receiver according to claim 3,
wherein the bias circuit and the PD are installed on an upper surface of a first subcarrier,
the TIA is installed on an upper surface of a second subcarrier, and
the first subcarrier and the second subcarrier are separated.

15. The optical receiver according to claim 2, wherein the bias circuit, the PD, and the TIA are installed on a single subcarrier.

16. The optical receiver according to claim 3, wherein the bias circuit, the PD, and the TIA are installed on a single subcarrier.

17. The optical receiver according to claim 2, wherein at least one of height of the upper surface of the PD and height of the upper surface of the bias circuit connected by the high frequency wiring board, and height of the upper surface of the PD and height of the upper surface of the TIA connected by the high frequency wiring board is adjusted by at least one of a step provided on the upper surface of the subcarrier and polishing of the PD.

18. The optical receiver according to claim 3, wherein at least one of height of the upper surface of the PD and height of the upper surface of the bias circuit connected by the high frequency wiring board, and height of the upper surface of the PD and height of the upper surface of the TIA connected by the high frequency wiring board is adjusted by at least one of a step provided on the upper surface of the subcarrier and polishing of the PD.
